(19) United States
(12) Patent Application Publication
(10) Pub. No.: US 2013/0000959 A1
(43) Pub. Date: Jan. 3, 2013

(54) TOUCH PANEL

(75) Inventors: Ho Joon Park, Seoul (KR); Ji Soo Lee, Gyunggi-do (KR)

(73) Assignee: SAMSUNG ELECTRO-MECHANICS CO., LTD., Gyunngi-do (KR)

(21) Appl. No.: 13/349,708

(22) Filed: Jan. 13, 2012

(30) Foreign Application Priority Data
Jun. 28, 2011 (KR) 1020110063174

(51) Int. Cl. H05K 1/09; H05K 1/00

(52) U.S. Cl. 174/257; 174/250

(57) ABSTRACT

Disclosed herein is a touch panel including: a base member including a body part and a connection part extended and protruded from the body part; a mesh shaped first transparent electrode formed on one surface of the base member and made of a metal, a mesh shaped second transparent electrode formed on the other surface of the base member and made of a metal; a first electrode wiring formed on one surface of the base member so that one end thereof is connected integrally to the first transparent electrode and the other end thereof is extended up to the connection part; and a second electrode wiring formed on the other surface of the base member so that one end thereof is connected integrally to the second transparent electrode and the other end thereof is extended up to the connection part.

### CROSS REFERENCE TO RELATED APPLICATION

This application claims the benefit of Korean Patent Application No. 10-2011-0063174, filed on Jun. 28, 2011, entitled “Touch Panel” which is hereby incorporated by reference in its entirety into this application.

### BACKGROUND OF THE INVENTION

1. Technical Field

The present invention relates to a touch panel.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has been widening the use of computers more and more, it is difficult to efficiently operate products using only a keyboard and mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, or a cathode ray tube (CRT) to thereby be used to allow a user to select desired information while viewing the image display device.

The touch panel is classified into a resistive type of touch panel, a capacitive type of touch panel, an electromagnetic type of touch panel, a surface acoustic wave (SAW) type of touch panel, and an infrared type of touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type of touch panel and the capacitive type of touch panel have been prominently used in a wide range of fields.

The resistive type of touch panel has a form in which upper and lower transparent electrode films are disposed to be spaced apart from each other by a spacer and are in contact with each other by pressing. In the case of the resistive type of touch panel, when an upper touch panel including the upper transparent electrode film formed thereon is pressed by an input unit such as fingers, pens, or the like, the upper and lower transparent electrode films are electrically conducted to each other, and a change in voltage according to a change in resistance value in the pressed position is recognized by a controlling part, such that the touched coordinates are recognized. As the resistive type of touch panel, there are a digital resistive type of touch panel and an analog resistive type of touch panel.

In the case of the capacitive type of touch panel, an upper substrate including a first transparent electrode formed thereon and a lower substrate including a second transparent electrode formed therein are spaced apart from each other, and the first and second transparent electrodes include an insulator inserted therebetween so that they are not in contact with each other. In addition, the upper and lower substrates include electrode wirings formed thereon, the electrode wirings being connected to the transparent electrodes. The electrode wirings transfer a change in capacitance generated in the first and second transparent electrodes as the touch screen is touched by the input unit to a controlling part.

Meanwhile, according to the prior art, the transparent electrode is made of indium tin oxide (ITO) or a conductive polymer such as polyethylene dioxythiophene/polystyrene sulfonate (PEDOT/PSS). The ITO has excellent electrical conductivity but is expensive due to indium that is a rare earth metal used as a raw material thereof. As a result, the indium is expected to be depleted within the next decade, such that it may not be smoothly supplied. The conductive polymer, which is a material emerged for substituting for the ITO, has excellent flexibility and easy machining capability but has degraded electrical conductivity.

Therefore, research into a technology of forming the transparent electrode using a metal that has excellent electrical conductivity and is easily in view of supply as compared with the ITO or the conductive polymer has currently progressed. However, at the time of forming the transparent electrode using the metal, the transmittance of the touch panel has deteriorated due to an opaque metal color.

In addition, according to the prior art, the transparent electrode and the electrode wiring are individually formed and then connected to each other, and the electrode wiring is again connected to a flexible printed cable through a conductive adhesive to thereby be connected to the controlling part. As a result, a process of manufacturing the touch panel becomes complicated, thereby causing an increase in process time. In addition, a defect occurs in the connection between the transparent electrode and the electrode wiring or the connection between the electrode wiring and the flexible printed cable, thereby deteriorating reliability.

### SUMMARY OF THE INVENTION

The present invention has been made in an effort to provide a touch panel reducing a time required for a manufacturing process thereof, having high connection reliability, and including a transparent electrode made of a metal.

According to a first preferred embodiment of the present invention, there is provided a touch panel including: a base member including a body part and a connection part extended and protruded from the body part; a first transparent electrode formed on one surface of the base member and having a mesh shape including a plurality of openings surrounded by a line patterned with a metal; a second transparent electrode formed on the other surface of the base member and having a mesh shape including a plurality of openings surrounded by a line patterned with a metal; a first electrode wiring formed on one surface of the base member so that one end thereof is connected integrally to the first transparent electrode and the other end thereof is extended up to the connection part; and a second electrode wiring formed on the other surface of the base member so that one end thereof is connected integrally to the second transparent electrode and the other end thereof is extended up to the connection part.

The first and second transparent electrodes may be made of copper (Cu), aluminum (Al), gold (Au), or silver (Ag).

Widths of the lines patterned with the metal of the first and second transparent electrodes may be 1 μm to 10 μm.

Thicknesses of the lines patterned with the metal of the first and second transparent electrodes may be 0.01 μm to 2 μm.

Sheet resistances of the first and second transparent electrodes may be 150 Ω/□ or less.

Transmittance of the touch panel may be 88% or more.

Surfaces of the first and second transparent electrodes may be subjected to black oxide treatment.

According to a second preferred embodiment of the present invention, there is provided a touch panel including: a transparent window including a body part and a connection part extended and protruded from the body part and having one surface touched; a transparent electrode formed on the other surface of the transparent window to have a mesh shape including a plurality of openings surrounded by a line patterned with a metal; and an electrode wiring formed on the other surface of the transparent window so that one end thereof is connected integrally to the transparent electrode and the other end thereof is extended up to the connection part.

The transparent electrode may be made of copper (Cu), aluminum (Al), gold (Au), or silver (Ag).

A width of the line patterned with the metal of the transparent electrode may be 1 μm to 10 μm.

A thickness of the line patterned with the metal of the transparent electrode may be 0.01 μm to 2 μm.

A sheet resistance of the transparent electrodes may be 150 Ω/□ or less.

Transmittance of the touch panel may be 88% or more.

A surface of the transparent electrode may be subjected to black oxide treatment.

### BRIEF DESCRIPTION OF THE DRAWINGS

FIG. 1 is a perspective view of a touch panel according to a first preferred embodiment of the present invention;

FIG. 2 is a cross-sectional view of a touch panel according to a first preferred embodiment of the present invention;

FIG. 3 is a perspective view of a base member;

FIG. 4A is an enlarged view of part A of FIG. 1;

FIGS. 4B and 4C are enlarged views showing a modified example of a mesh shape;

FIG. 5 is an enlarged view of part B of FIG. 1;

FIG. 6 is a cross-sectional view of a touch panel according to a second preferred embodiment of the present invention; and

FIG. 7 is a rear perspective view of a touch panel according to a second preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

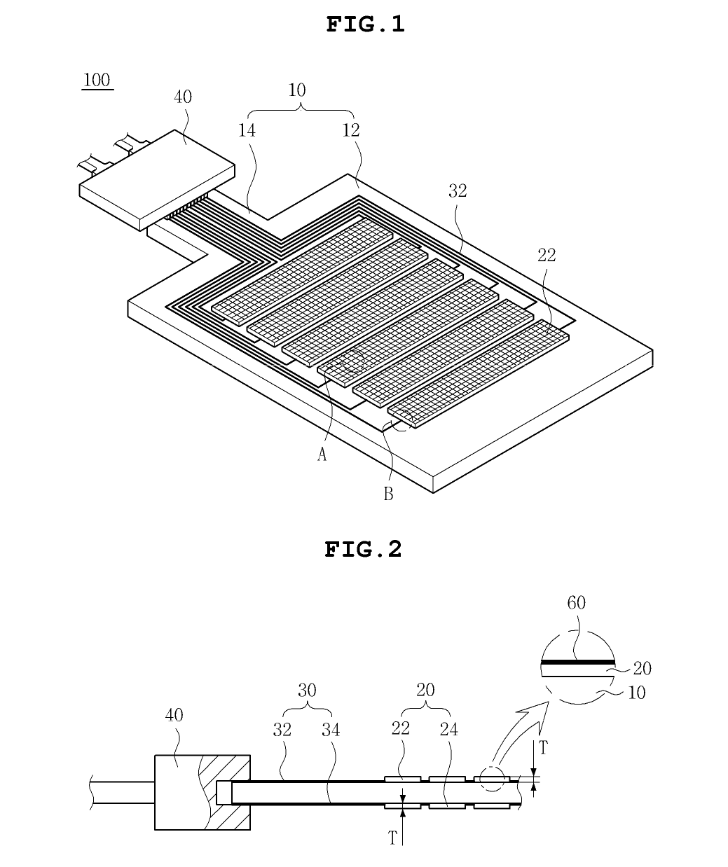

A touch panel according to a first preferred embodiment of the present invention includes a base member 10 including a body part 12 and a connection part 14 extended and protruded from the body part 12, a mesh shaped first transparent electrode 22 formed on one surface of the base member 10 and made of a metal, a mesh shaped second transparent electrode 24 formed on the other surface of the base member 10 and made of a metal, a first electrode wiring 32 formed on one surface of the base member 10 so that one end thereof is connected integrally to the first transparent electrode 22 and the other end thereof is extended up to the connection part 14, and a second electrode wiring 34 formed on the other surface of the base member 10 so that one end thereof is connected integrally to the second transparent electrode 24 and the other end thereof is extended up to the connection part 14, as shown in FIGS. 1 and 2. According to the preferred embodiment of the present invention, transparent electrodes 20 and electrode wirings 30 are formed integrally with each other on both surfaces of the base member 10 including the body part 12 and the connection part 14 is directly connected to a controlling part 40, thereby making it possible to significantly reduce a time required for a manufacturing process of a touch panel and prevent a connection defect. Hereinafter, each component of the present invention will be described in detail.

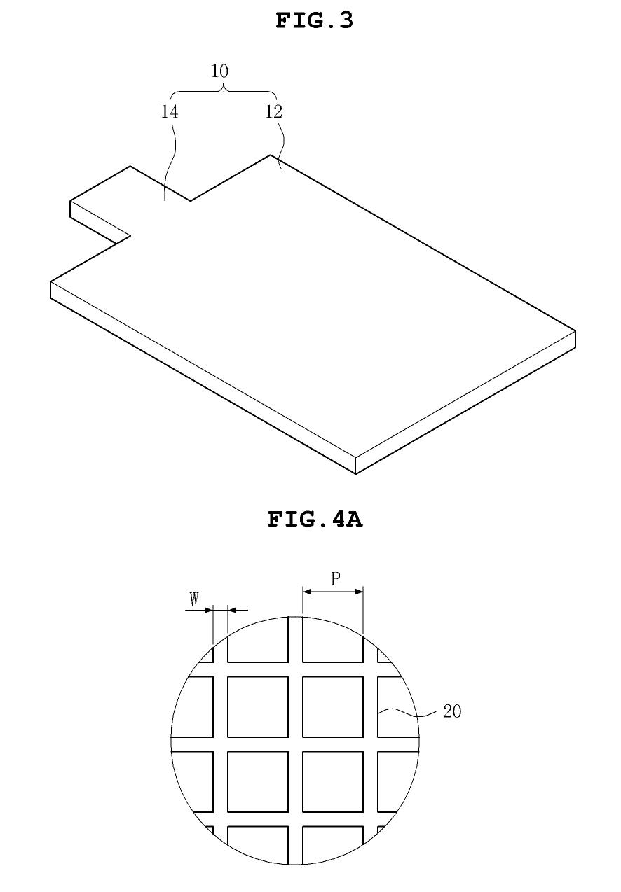

First, the base member 10 includes the body part 12 and the connection part 14 extended and protruded from the body part 12, as shown in FIG. 3. According to the preferred embodiment of the present invention, the base member 10 and the controlling part 40 (See FIG. 2) are directly connected to each other through the connection part 14 included in the base member 10, thereby making it possible to omit a flexible printed cable. Therefore, a manufacturing process of the touch panel is simplified, and only the connection between the connection part 14 and the controlling part 40 is performed to reduce the number of connection processes, thereby reducing a risk of occurrence of a connection defect. The connection part 14 has a quadrangular shape in the drawings. However, the shape of the connection part 14 is not necessarily limited thereto but may have various shapes in consideration of the connection with the controlling part 40.

In addition, the base member 10 according to the preferred embodiment of the present invention is made of a material having support force capable of supporting the transparent electrode 20 (See FIG. 2) and the electrode wiring 30 (See FIG. 2) and transparency allowing a user to recognize images provided on a display. The base member 10 may be made of polyethylene terephthalate (PET), polycarbonate (PC), poly methyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, or tempered glass, but is not necessarily limited thereto.

Next, the first and second transparent electrodes 22 and 24 are formed to have a mesh shape on both surfaces of the base member 10, respectively, as shown in FIG. 2. More specifically, the first transparent electrode 22 is formed on one surface of the base member 10 so as to have a mesh shape including a plurality of openings surrounded by a line patterned with a metal, and the second transparent electrode 24 is formed on the other surface of the base member 10 so as to have a mesh shape, similar to the first transparent electrode 22. The transparent electrode 20 is a portion sensing a change in capacitance (a capacitive type) or a change in resistance value (a resistive type) when a user's hand touches a touch screen.

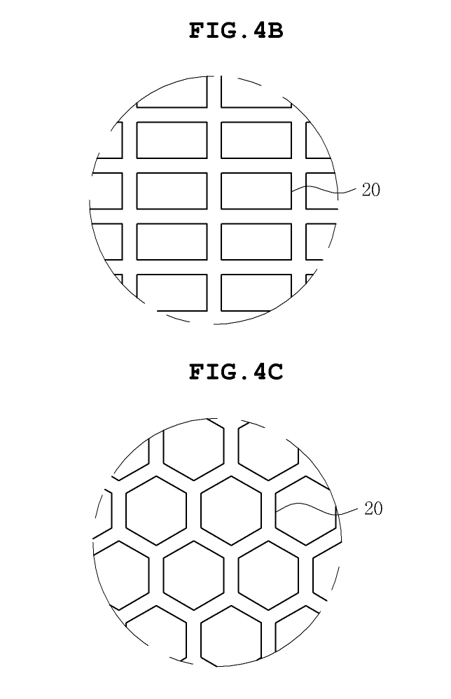

The transparent electrode 20 according to the preferred embodiment of the present invention is formed to have a mesh shape as shown in FIG. 4A. The mesh shape generally indicates a shape in which a plurality of square openings are uniformly arranged in a predetermined area When the transparent electrode 20 is made of a metal, the transparent electrode has excellent electrical conductivity but reduces the transmittance of the touch panel (a ratio of incident light to transmitting light) due to an opaque metal color. According to the preferred embodiment of the present invention, the transparent electrode 20 is formed to have a mesh shape in a predetermined area to make a size of a mesh pitch fine at several μm, such that an aperture ratio (a ratio of the opening area to the entire area) may reach 95% to 99.5%. Therefore, the opening area of the transparent electrode 20 easily transmitting light increases, thereby making it possible to improve the transmittance of the touch panel. Here, a pitch P of the mesh indicates a length of one side of a single square opening and a line width W indicates a width of a patterned single metal line surrounding the opening, as shown in FIG. 4A.

The mesh shape is not limited to the square opening shape but may be an opening shape such as a rectangular shape (see FIG. 4B), a polygonal shape such as a hexagon (see FIG. 4C), or the like, an oval shape, a circular shape, or the like.

In this case, the line width W of the transparent electrode 20 may be 1 μm to 10 μm. The touch panel has excellent transmittance of 88% or more within this range.

Further, a thickness T (See FIG. 2) of the transparent electrode 20 may be 0.01 μm to 2 μm. When the thickness T of the transparent electrode 20 is less than 0.01 μm, electrical conductivity may be reduced, and when it exceeds 2 μm, the transmittance of the touch panel may be reduced.

As a metal material forming the transparent electrode 20, copper (Cu), aluminum (Al), gold (Au), silver (Ag), titanium (Ti), palladium (Pd), chromium (Cr), or a combination thereof may be used. The transparent electrode 20 may be made of copper (Cu), aluminum (Al), gold (Au), or silver (Ag), all of which have excellent electrical conductivity. However, the preferred embodiment of the present invention is not limited thereto. As a result, all the metals that has high electrical conductivity and is easily processed may be used as a material of the transparent electrode 20. According to the preferred embodiment of the present invention, the transparent electrode 20 is made of a metal, thereby having high electrical conductivity of 150 Ω/□ or less of sheet resistance.

Meanwhile, as shown in an enlarged view of FIG. 2, when the transparent electrode 20 is made of copper (Cu), a surface of the transparent electrode 20 may be subjected to black oxide treatment 60. Here, the black oxide treatment 60 indicates treatment in which Cu₂O or CuO is precipitated by oxidizing the surface of the transparent electrode 20 at a temperature of 100□ or more, wherein the Cu₂O is brown and is thus referred to as a brown oxide and the CuO is black and is thus referred to as black oxide. The black oxide treatment 60 is performed on the surface of the transparent electrode 20 to prevent light from being reflected from the transparent electrode 20, thereby improving the visibility of the touch panel.

Next, the electrode wirings 30 are formed to be connected to one end or both ends of the transparent electrodes 20. More specifically, the first electrode wiring 32 is formed on one surface of the base member 10 so that one end thereof is connected integrally to the first transparent electrode 22 and the other end thereof is extended up to the connection part 14. Likewise, the second electrode wiring 34 is formed on the other surface of the base member 10 so that it is connected integrally to the second transparent electrode 24 and is extended up to the connection part 14. Each of the first and second electrode wirings 32 and 34 is collected on both surfaces of the connection part 14 to thereby be electrically connected to the controlling part 40. The electrode wirings 30 serve to receive electrical signals from the transparent electrodes 20 and transmit the received electrical signals to the controlling part 40.

According to the preferred embodiment of the present invention, one end of the electrode wiring 30 is formed to be connected integrally to the transparent electrode 20. That is, the electrode wiring 30 and the transparent electrode 20 may be made of the same metal material and be formed at the same time. According to the preferred embodiment of the present invention, the electrode wirings 30 are connected integrally to the transparent electrodes 20 on both surfaces of the base member 10, thereby making it possible to form the transparent electrodes 20 and the electrode wirings 30 on both surfaces of the base member 10 through a single process. In addition, since the electrode wirings 30 are extended up to the connection part 14 of the base member 10 to thereby be directly connected to the controlling part 40, a connection process of the flexible printed cable is omitted. Therefore, a structure of the touch panel according to the preferred embodiment of the present invention may significantly reduce a time required for a manufacturing process of the touch panel, as compared to the structure according to the prior art. Furthermore, since the electrode wirings 30 are formed integrally with the transparent electrodes 20 at the time of the formation of the transparent electrodes 20 without performing a separate connection process, a problem such as step generation or a connection defect may be prevented.

The electrode wiring 30 may be made of silver (Ag) as a material having high electrical conductivity. However, the preferred embodiment of the present invention is not limited thereto and the electrode wiring 30 may be made of copper (Cu), aluminum (Al), gold (Au), silver (Ag), titanium (Ti), palladium (Pd), chromium (Cr), or a combination thereof, similar to the transparent electrode 20.

In addition, the transparent electrode 20 and the electrode wiring 30 may be formed on the base member 10 by plating, sputtering, evaporation, or the like or may be formed at the same time by a printing process such as a silk screen method, a gravure printing method, or an inkjet printing method.

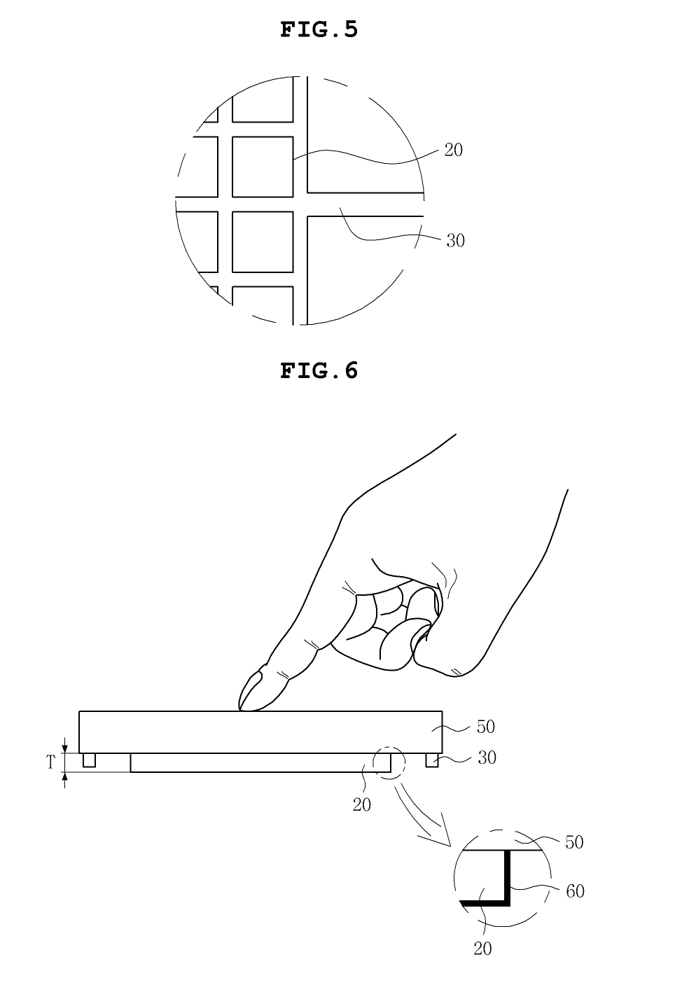

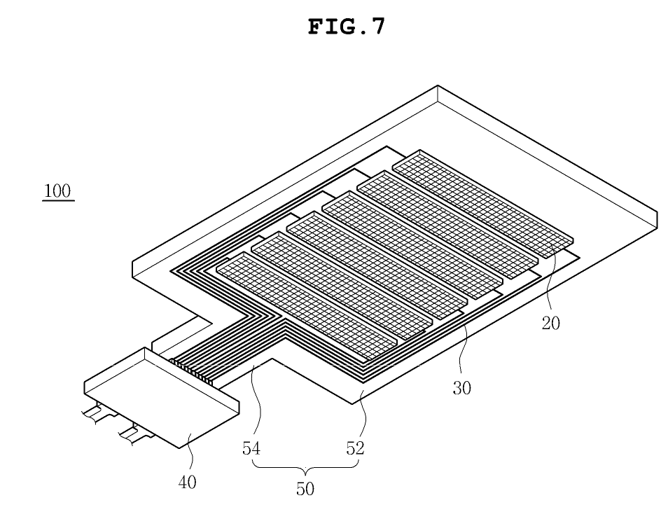

A touch panel according to a second preferred embodiment of the present invention includes a transparent window 50 including a body part 52 and a connection part 54 extended and protruded from the body part 52 and having one surface touched, a transparent electrode 20 formed on the other surface of the transparent window 50 to have a mesh shape including a plurality of openings surrounded by a line patterned with a metal, and an electrode wiring 30 formed on the other surface of the transparent window 50 so that one end thereof is connected integrally to the transparent electrode 20 and the other end thereof is extended up to the connection part 54, as shown in FIGS. 6 and 7. According to the preferred embodiment of the present invention, the transparent electrode 20 and the electrode wiring 30 are formed integrally with each other on the transparent window 50 including the body part 52 and the connection part 54 is directly connected to a controlling part 40, thereby making it possible to significantly reduce a time required for a manufacturing process of a touch panel and prevent a connection defect. Hereinafter, each component of the present invention will be described in detail. A portion overlapped with the above-mentioned portion will be omitted or be simply described.

First, the transparent window 50 according to the preferred embodiment of the present invention includes the body part 52 and the connection part 54 extended and protruded from the body part 52. According to the preferred embodiment of the present invention, the transparent window 50 and the controlling part 40 are directly connected to each other through the connection part 54 included in the transparent window 50, thereby making it possible to omit a flexible printed cable. Therefore, a manufacturing process of the touch panel is simplified, and only the connection between the connection part 54 and the controlling part 40 is performed to reduce the number of connection process, thereby reducing a risk of occurrence of a connection defect.

The transparent window 50 is made of a material having support force capable of supporting the transparent electrode 20 and the electrode wiring 30 and transparency allowing a user to recognize images provided on a display. The transparent window 50 may be made of polyethylene terephthalate (PET), polycarbonate (PC), poly methyl methacrylate (PMMA), polyethylene naphthalate (PEN), polyethersulpon (PES), cyclic olefin polymer (COC), triacetylcellulose (TAC) film, polyvinyl alcohol (PVA) film, polyimide (PI) film, polystyrene (PS), biaxially stretched polystyrene (K resin containing biaxially oriented PS; BOPS), glass, or tempered glass, but is not necessarily limited thereto.

In addition, one surface of the transparent window 50 is a portion directly touched by the user, as shown in FIG. 6. That is, one surface of the transparent window 50 is a surface directly touched by a hand of the user or an object in order to allow the user to input a command or perform a series of operations while viewing an image penetrating through the touch panel. According to the preferred embodiment of the present invention, the transparent electrode 20 is directly formed on the transparent window 50, such that the base member may be omitted, thereby making it possible to manufacture a touch panel having a thin and significantly simple structure.

Next, the transparent electrode 20 is formed on the transparent window 50 so as to have the mesh shape, as shown in FIG. 7. As described in detail above, the transparent electrode 20 is formed on the other surface of the transparent window 50 so as to have the mesh shape including the plurality of openings surrounded by the line patterned with the metal. According to the preferred embodiment of the present invention, the transparent electrode 20 is formed to have the mesh shape, thereby having excellent transmittance.

In this case, the line width W (See FIG. 4A) of the transparent electrode 20 may be 1 μm to 10 μm. The touch panel has excellent transmittance of 88% or more and the transparent electrode 20 also has good electrical conductivity, within this range.

Further, a thickness T of the transparent electrode 20 may be 0.01 μm to 2 μm. When the thickness T of the transparent electrode 20 is less than 0.01 μm, electrical conductivity may be reduced, and when it exceeds 2 μm, the transmittance of the touch panel may be reduced.

Meanwhile, as shown in an enlarged view of FIG. 6, when the transparent electrode 20 is made of copper (Cu), black oxide treatment 60 is performed on a surface of the transparent electrode 20 to prevent light from being reflected from the transparent electrode 20, thereby improving the visibility of the touch panel.

Next, the electrode wiring 30 is extended from the transparent electrode 20 to thereby be formed integrally with the transparent electrode 20 (See FIG. 5). That is, the electrode wiring 30 and the transparent electrode 20 may be made of the same metal material and be formed at the same time. In addition, since the electrode wiring 30 are extended up to the connection part 54 of the transparent window 50 to thereby be directly connected to the controlling part 40, a connection process of the flexible printed cable is omitted. Therefore, a structure of the touch panel according to the preferred embodiment of the present invention may significantly reduce a time required for a manufacturing process of the touch panel, as compared to the structure according to the prior art. Furthermore, since the electrode wirings 30 are formed integrally with the transparent electrodes 20 without performing a separate connection process, a problem such as step generation or a connection defect may be prevented. The electrode wiring 30 is collected on the connection part 54 to thereby be electrically connected to the controlling part 40.

As set forth above, according to the preferred embodiment of the present invention, the transparent electrodes and the electrode wirings are formed integrally with each other on both surfaces of the base member including the connection part, and the connection part of the base member is directly connected to the controlling part, thereby making it possible to reduce a time required for a manufacturing process of a touch panel and prevent a connection defect.

In addition, according to the preferred embodiment of the present invention, the transparent electrode and the electrode wiring are formed integrally with each other on the transparent window including the connection part and having one surface touched, and the connection part of the transparent window is directly connected to the controlling part, thereby making it possible to reduce a time required for a manufacturing process of a touch panel and prevent a connection defect.

Although the preferred embodiments of the present invention have been disclosed for illustrative purposes, they are for specifically explaining the present invention and thus a touch panel according to the present invention is not limited thereto, but those skilled in the art will appreciate that various modifications, additions and substitutions are possible, without departing from the scope and spirit of the invention as disclosed in the accompanying claims. Accordingly, such modifications and alterations should also be understood to fall within the scope of the present invention. A specific protective scope of the present invention could be defined by the accompanying claims.

What is claimed is:

1. A touch panel comprising:
a base member including a body part and a connection part extended and protruded from the body part;
a first transparent electrode formed on one surface of the base member and having a mesh shape including a plurality of openings surrounded by a line patterned with a metal;
a second transparent electrode formed on the other surface of the base member and having a mesh shape including a plurality of openings surrounded by a line patterned with a metal;
a first electrode wiring formed on one surface of the base member so that one end thereof is connected integrally to the first transparent electrode and the other end thereof is extended up to the connection part; and
a second electrode wiring formed on the other surface of the base member so that one end thereof is connected integrally to the second transparent electrode and the other end thereof is extended up to the connection part.

2. The touch panel as set forth in claim 1, wherein the first and second transparent electrodes are made of copper (Cu), aluminum (Al), gold (Au), or silver (Ag).

3. The touch panel as set forth in claim 1, wherein widths of the lines patterned with the metal of the first and second transparent electrodes are 1 μm to 10 μm.

4. The touch panel as set forth in claim 1, wherein thicknesses of the lines patterned with the metal of the first and second transparent electrodes are 0.01 μm to 2 μm.

5. The touch panel as set forth in claim 1, wherein sheet resistances of the first and second transparent electrodes are 150 Ω/□ or less.

6. The touch panel as set forth in claim 1, wherein transmittance of the touch panel is 88% or more.

7. The touch panel as set forth in claim 1, wherein surfaces of the first and second transparent electrodes are subjected to a black oxide treatment.

8. A touch panel comprising:
a transparent window including a body part and a connection part extended and protruded from the body part and having one surface touched;
a transparent electrode formed on the other surface of the transparent window to have a mesh shape including a plurality of openings surrounded by a line patterned with a metal; and
an electrode wiring formed on the other surface of the transparent window so that one end thereof is connected integrally to the transparent electrode and the other end thereof is extended up to the connection part.

9. The touch panel as set forth in claim 8, wherein the transparent electrode is made of copper (Cu), aluminum (Al), gold (Au), or silver (Ag).

10. The touch panel as set forth in claim 8, wherein a width of the line patterned with the metal of the transparent electrode is 1 μm to 10 μm.

11. The touch panel as set forth in claim 8, wherein a thickness of the line patterned with the metal of the transparent electrode is 0.01 μm to 2 μm.

12. The touch panel as set forth in claim 8, wherein a sheet resistance of the transparent electrodes is 150 Ω/□ or less.

13. The touch panel as set forth in claim 8, wherein transmittance of the touch panel is 88% or more.

14. The touch panel as set forth in claim 8, wherein a surface of the transparent electrode is subjected to a black oxide treatment.
